(19) United States
(12) Patent Application Publication
(10) Pub. No.: US 2008/0115910 A1
(43) Pub. Date: May 22, 2008

(54) Heat-Dissipation and Airflow-Conduction Fin Assembly

(76) Inventor: Hsing Ju Sheng, Ba-Li Shiang (TW)

Correspondence Address: HDSL, 4331 STEVENS BATTLE LANE, FAIRFAX, VA, 22033, US

(21) Appl. No.: 11/562,406

(22) Filed: Nov. 21, 2006

(51) Int. Cl. H05K 7/20

(52) U.S. Cl. 165/80.3; 361/710

(57) ABSTRACT

A heat-dissipation and airflow-conductive fin assembly is constructed by a plurality of heat-dissipation and heat-conductive fins. The fin includes a base plate with a pair of openings. A pair of side plates is extended perpendicularly from opposite edges of the base plate. The side plates further extend to form inward flanges which are parallel to the base plate. Thus, the base plate, the side plates and the flanges form an airflow channel. A pair of tab engagements is respectively extended from the flanges in the direction reverse to the base plate. The tab engagements on the flanges are at the positions corresponded to the positions of the openings. Thus, the tab engagement is capable to be firmly engaged and irreversibly retained in the opening of another fin. The engagement of the fin assembly of the present invention can be simply assembled and avoid the occurrence of disengagement. The heat-dissipation fin assembly assembled by the present heat-dissipation and airflow-conductive fins forms larger areas for heat dissipation and decreases the air friction in the airflow channel, thereby achieves and obtains an optimal cooling effect.

### BACKGROUND OF THE INVENTION

1. Field of the Invention

The present invention relates to a heat dissipation fin assembly, and in particular to a heat-absorption, heat-dissipation and airflow-conduction fin assembly which is capable to conduct the direction of airflow.

2. Description of the Related Art

A conventional heat-dissipation fin assembly is constructed by a plurality of heat-dissipation fins. The fin assembly comprises a plurality of heat-dissipation fins to form a plurality of air passages between the fins. The formed air passages are capable to conduct the airflow induced by a cooling fan disposed at one end of the fin assembly to the other end thereof and thus exhaust away the heat generated from heat source, such as the electronic elements or devices.

Since the conventional heat-dissipation fin assembly is manufactured by riveted engagement of one fin to another, it not only takes time for manufacturing but also reduces the precision of the assembly. A poor precision of the fin assembly results in the interruption of heat conduction. Thus, the conventional manufacturing of heat-dissipation assembly is complicated, time-consuming and costly. A fin with tongues and openings is disclosed to simplify the manufacturing of the fin assembly. The tongues of the fin can be fitted into an opening of the other fin in order to engage one with another to form a fin assembly. A shape of the tongues is various, such as in a U-shape or dovetail shape. However, it takes time to exactly fit the tongues of one fin into the openings of another one fin. Moreover, the engagement of the fins is easily disengaged or disassembled. The disengagement of the fin assembly results in the interruption in the heat conduction and increases the reflection and static pressure of the airflow, thereby decreases the cooling efficiency of the fin assembly.

### SUMMARY OF THE INVENTION

Accordingly, the present invention is to provide a heat-dissipation and airflow-conductive fin assembly. The heat-dissipation and airflow-conductive fin assembly is assembled by a plurality of heat-dissipation fins. The heat-dissipation and airflow-conductive fin assembly displays outer edges of the heat-dissipation fin as even planes to form larger areas for heat dissipation. Moreover, the engagement of the fin assembly of the present invention is irreversible to avoid the occurrence of disengagement. In addition, the air friction in the airflow channel of the heat-dissipation and airflow-conductive fin assembly is decreased and the heat absorption thereof is enhanced, thereby the present fin assembly achieves and obtains an optimal cooling effect.

The present invention discloses a heat-dissipation and airflow-conductive fin assembly. The fin assembly is constructed by a plurality of heat-dissipation and heat-conductive fins. The fin comprises a base plate with a pair of openings. A pair of side plates is extended perpendicularly from opposite edges of the base plate. The side plates further respectively extend to form inward flanges which are parallel to the base plate. Thus, the base plate, the side plates and the flanges form an airflow channel. A pair of tab engagements is respectively extended from the flanges in the direction reverse to the base plate. The tab engagements on the flanges are at the positions corresponded to the positions of the openings on the base plate. The tab engagement has a slot to divide the tab engagement into two barb parts. The barb parts respectively have bevel edges.

During assembly, the pair of the tab engagements is fitted into the openings of another heat-dissipation fin. When fitting the tab engagements, the bevel edges thereof are forced by the restriction of the openings, and the slot thus is pressed to make the bevel edges closer in order to be fitted into the opening. After the bevel edges get through the opening, the barb parts are released to the original alignment. Thus, the tab engagement is firmly engaged and irreversibly retained in the opening.

### DESCRIPTION OF THE DRAWINGS

The invention can be more fully understood by reading the subsequent detailed description in conjunction with the examples and references made to the accompanying drawings, wherein:

FIG. 1 is a perspective view of a heat dissipation fin according to the present invention;

FIG. 2 is a perspective view of an assembly assembled by a plurality of the heat dissipation fins according to the present invention;

FIG. 3 is a perspective view of a cooling fan incorporated with the heat-dissipation fin assembly according to the present invention;

FIG. 4 is a perspective view of a second embodiment of the present invention; and

FIG. 5 is a perspective view of a cooling fan incorporated with the heat-dissipation fin assembly illustrated in FIG. 4 according to the present invention.

### DETAILED DESCRIPTION OF THE INVENTION

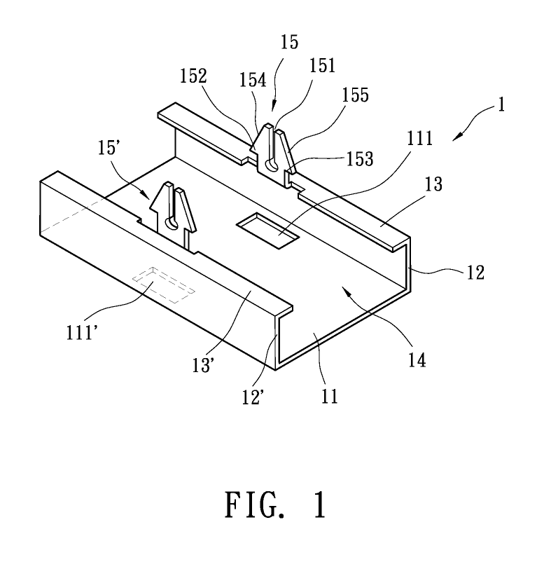

FIG. 1 is a perspective view of a heat dissipation fin according to the present invention. The heat-dissipation fin assembly is constructed by a plurality of heat-dissipation and airflow-conductive fins 1. The fin 1 comprises a base plate 11 with a pair of openings 111, 111′. A pair of side plates 12, 12′ is extended perpendicularly from opposite edges of the base plate 11. The side plates 12, 12′ further extend to form inward flanges 13, 13′ which are parallel to the base plate 11. Thus, the base plate 11, the side plates 12, 12′ and the flanges 13, 13′ form an airflow channel 14. A pair of tab engagements 15-15′ is respectively extended from the flanges 13, 13′ in the direction reverse to the base plate. The tab engagements 15, 15′ on the flanges 13, 13′ are at the positions corresponded to the positions of the openings 111, 111 ′ on the base plate. In the present embodiment as shown in FIG. 1, the tab engagement 15 is in an arrowhead shape with a slot 151 to divide the tab engagement 15 into two barb parts 152,153. The barb parts 152, 153 respectively have bevel edges 154, 155.

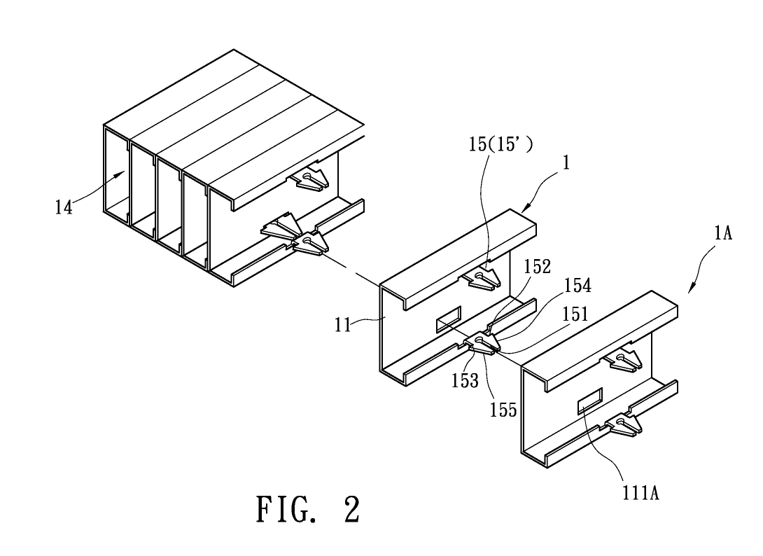

FIG. 2 is a perspective view of a fin assembly assembled by a plurality of the heat dissipation fins according to the present invention. The heat-dissipation and airflow-conductive fin assembly is assembled by a plurality of heat-dissipation fins 1. During assembly, the tab engagements 15, 15′ are fitted into the opening 111A of another heat-dissipation fin 1A. When fitting the tab engagements, the bevel edges 154, 155 thereof are forced by the restrictions of the opening 111A, and the slot 151 thus is pressed to make the bevel edges 154-155 closer in order to be fitted in to the opening 111A. After the bevel edges 154, 155 get through the opening, the barb parts 152, 153 is released to the original alignment. Thus, the tab engagement 15 is firmly engaged and retained in the opening 111A. Accordingly, a plurality of heat-dissipation and heat-conductive fins 1 is formed a plurality of airflow channels 14.

The engagement of the present heat-dissipation fins, as described above, is conducted on the base plate area of the fins 1 so as to display the outer edges of the heat-dissipation fin as even planes. Thus, the present fin assembly will form larger areas for heat dissipation. In addition, the tab engagements of arrowhead shape are irreversibly retained in the openings of the fins, so that the occurrence of disengagement is avoided. Moreover, due to the firmly irreversibly engagement of the fin assembly of the present invention, the air friction in the airflow channel is decreased and air force is increased, the present fin assembly achieves and obtains an optimal cooling effect.

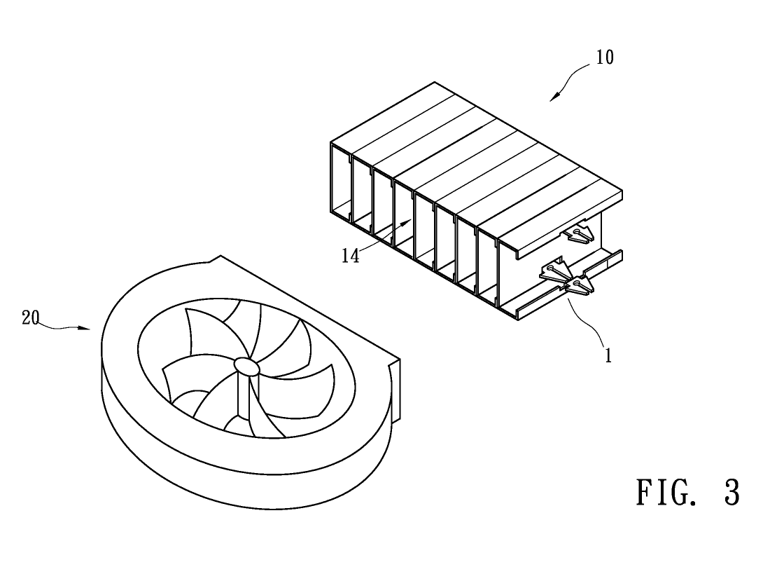

FIG. 3 is a perspective view of a cooling fan incorporated with the heat-dissipation fin assembly according to the present invention. A cooling fan 20 is disposed at one end of the heat-dissipation fin assembly 10. When the cooling fan working, the airflow generated by the cooling fan 20 is blown into the plurality of airflow channels 14 of the heat-dissipation assembly 10. The airflow channels 14 direct the airflow to the other end of the present fin assembly 1 so as to exhaust the heat from the heat source, such as electric elements and devices.

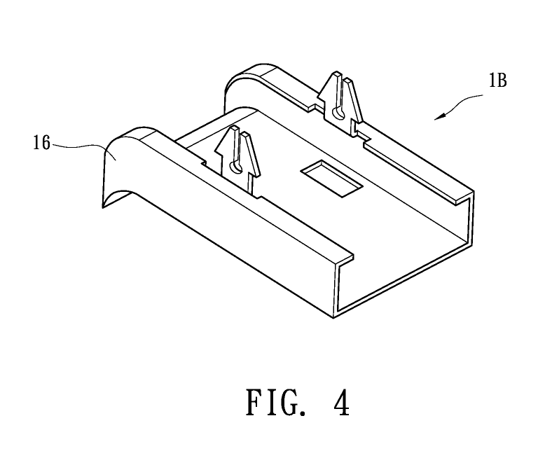

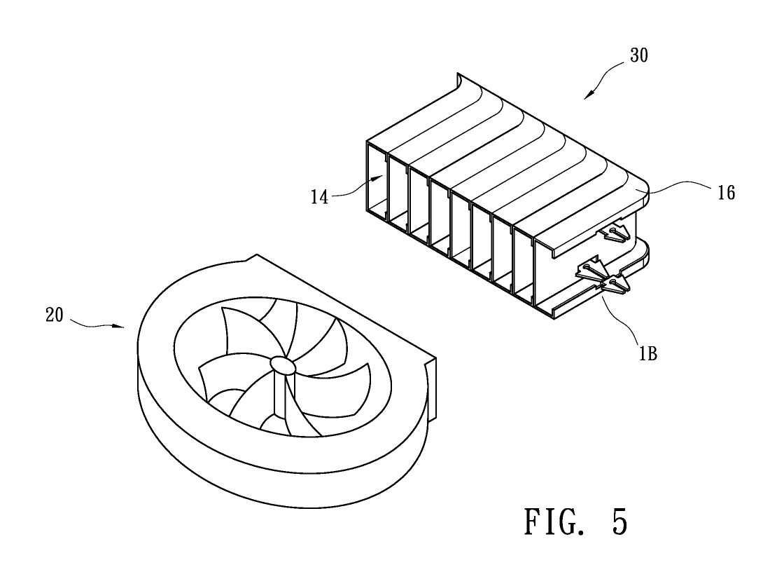

FIG. 4 is a perspective view of another embodiment of the present invention. As shown in FIG. 4, the main elements of the heat-dissipation and airflow-conductive fin 1B are similar to the heat-dissipation fin 1 as illustrated in FIG. 1, except that one end of the heat-dissipation and airflow-conductive fin 1B is formed in a curved end 16. Thus, after assembling a plurality of the heat-dissipation and airflow-conductive fins 1B, the fin assembly 30 as shown in FIG. 5 is with a curved end 16. The curved end 16 of the fin assembly is capable to direct the airflow so as to exhaust the heat generated from the heat source to the designed direction. The fin assembly with curved end 16 is capable to operate in accordance with the position of cooling fans on the motherboard to conduct the reflective heat flow, decrease the air friction and increase the air force in order to enhance the heat-dissipation efficiency. The present fin assembly is also capable to operate with any type of cooling fans, such as centrifugal fan and axial fan to achieve and obtain an optima cooling efficiency.

FIG. 5 is a perspective view of a cooling fan incorporated with the heat-dissipation fin assembly of FIG. 4 according to the present invention. A cooling fan 20 is disposed at one end of the fin assembly 30. When the cooling fan 20 is working, the airflow generated therefrom is blown into the airflow channels 14 of the fin assembly 30 and out from the curved end 16 thereof so as to exhaust out the heat generated from the heat source. The curved end 16 of the fin assembly 30 is capable to smoothly direct the airflow and to avoid the reflection of the airflow which will cause the disturbance of airflow. Due to the curved end 16 of the fin assembly 30, the static pressure in the airflow channels will be decreased. In addition, the curved end of the fin assembly is able to conduct the airflow to the designed direction in order to cool the heat sources, such as electric elements and devices.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A heat-dissipation and airflow-conductive fin assembly constructed by a plurality of heat-dissipation and heat-conductive fins, which comprises
a base plate with a pair of openings;
a pair of side plates extended perpendicularly from opposite edges of the base plate;
a pair of inward flanges extended from the side plates and parallel to the base plate so as to the base plate, the side plates and the flanges form an airflow channel; and
a pair of tab engagements respectively perpendicularly extendeding from the flanges in a direction reverse to the base plate at positions corresponded to the positions of the openings,
thereby, during assembly, the pair of the tab engagements is fitted into the openings of another heat-dissipation and airflow-conductive fin.

2. The heat-dissipation and airflow-conductive fin assembly as claimed in claim 1, wherein the tab engagement is in an arrowhead shape.

3. The heat-dissipation and airflow-conductive fin assembly as claimed in 2, wherein the tab engagement has a slot to divide the tab engagement into two barb parts, and the barb parts respectively have bevel edges.

4. The heat-dissipation and airflow-conductive fin assembly as claimed in claim 1, wherein one end of the fin assembly is formed in a curved shape in order to direct the airflow in the airflow channel.
